(19) United States
(12) Patent Application Publication
(10) Pub. No.: US 2024/0312023 A1
(43) Pub. Date: Sep. 19, 2024

(54) CONTOUR LINE PROCESSING METHOD AND ELECTRONIC DEVICE

(71) Applicants: Inventec (Pudong) Technology Corp., Shanghai (CN); Inventec Corporation, Taipei (TW)

(72) Inventors: Ping-Jung Lu, Taipei (TW); I-Chang Wang, Taipei (TW)

(73) Assignees: Inventec (Pudong) Technology Corp., Shanghai (CN); Inventec Corporation, Taipei (TW)

(21) Appl. No.: 18/211,244

(22) Filed: Jun. 17, 2023

(30) Foreign Application Priority Data
Mar. 14, 2023 (CN) 202310246254.0

(51) Int. Cl. G06T 7/12; G06F 30/10

(52) U.S. Cl. CPC G06T 7/12; G06F 30/10; G06T 2207/20021; G06T 2207/20036

(57) ABSTRACT

A contour line processing method is provided, which includes obtaining a computer-aided design image file and detecting a plurality of line segments from the computer-aided design image file, performing a first morphological operation on the plurality of line segments to generate a plurality of blocks, performing a union operation on the plurality of blocks to generate a union block, performing a second morphological operation on the union block to generate a processed block, and determining a target contour block according to the processed block.

### BACKGROUND OF THE INVENTION

### 1. Field of the Invention

The present invention relates to a contour line processing method an electronic device, and more particularly, to a contour line processing method and an electronic device capable of effectively extracting closed contour.

### 2. Description of the Prior Art

Computer-aided design (CAD) technology has been widely used in manufacturing design for various products. In general, it is necessary to estimate the area or weight of product objects during the product development stage. A product object in the CAD file may be formed by a plurality of discrete line segments. In order to estimate the area or weight of the product object, the sequence order relationship between the line segments is usually determined first, and end points of the line segments are found to connect according to the order of the line segments, such that the combination of the line segments may be converted to a contour block for facilitating estimation of area ratio or weight of the product object. However, if the end points of multiple line segments are too close, it is easy to make a misjudgment, so that the head and tail end points of the line segments cannot be correctly determined. Please refer to FIG. 1. FIG. 1 is a schematic diagram illustrating an open contour formed by misjudged endpoints of multiple line segments. As shown in the left half of FIG. 1, since there are multiple line segment endpoints intersecting and adjacent to each other in the middle area, judgment errors are often made and the endpoints of line segments cannot be effectively and correctly determined. As a result, as shown in the right half of FIG. 1, when the endpoints of multiple line segments are too close to each other, it is difficult to effectively distinguish the head and tail endpoints of the line segments for connection at the intersection of the middle area. Thus, gaps may occur in the middle area and the line segments are unable to form an enclosed contour, this may directly influence the estimation accuracy of area ratio or weight of the product object. Further, operations of analyzing the sequence relationship among all the line segments may also consume too much system resources. Thus, there is a need for improvement.

### SUMMARY OF THE INVENTION

It is therefore a primary objective of the present invention to provide a contour line processing method and an electronic device capable of effectively extracting closed contour, in order to resolve the aforementioned problems.

The present invention discloses a contour line processing method, comprising obtaining a computer-aided design (CAD) image file and detecting a plurality of line segments from the CAD image file; performing a first morphological operation on the plurality of line segments to generate a plurality of blocks; performing a union operation on the plurality of blocks to generate a union block; performing a second morphological operation on the union block to generate a processed block; and determining a target contour block according to the processed block.

The present invention further discloses an electronic system, comprising: a storage device, configured to store instructions; a processor circuit, configured to execute the instructions of: obtaining a CAD image file and detecting a plurality of line segments from the CAD image file; performing a first morphological operation on the plurality of line segments to generate a plurality of blocks; performing a union operation on the plurality of blocks to generate a union block; performing a second morphological operation on the union block to generate a processed block; and determining a target contour block according to the processed block.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating an open contour formed by misjudged endpoints of multiple line segments.

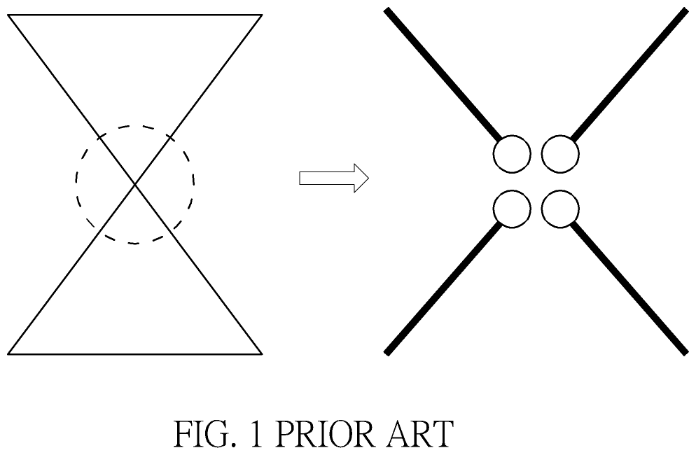

FIG. 2 is a flow diagram of a procedure according to an embodiment of the present invention.

FIG. 3 is a schematic diagram illustrating line segments in a CAD image file according to an embodiment of the present invention.

FIG. 4 is a schematic diagram illustrating the blocks after dilation operation process according to an embodiment of the invention.

FIG. 5 is a schematic diagram illustrating the block after the union operation process according to an embodiment of the present invention.

FIG. 6 is a schematic diagram illustrating the block after erosion operation process according to an embodiment of the invention.

FIG. 7 is a schematic diagram illustrating a target contour block according to an embodiment of the present invention.

FIG. 8 is a schematic diagram illustrating a contour block of a product object according to an embodiment of the present invention.

### DETAILED DESCRIPTION

Certain terms are used throughout the description and following claims to refer to particular components. As one skilled in the art will appreciate, hardware manufacturers may refer to a component by different names. This document does not intend to distinguish between components that differ in name but not function. In the following description and in the claims, the terms “include” and “comprise” are utilized in an open-ended fashion, and thus should be interpreted to mean “include, but not limited to”. Also, the term “couple” is intended to mean either an indirect or direct electrical connection. Accordingly, if one device is coupled to another device, that connection may be through a direct electrical connection, or through an indirect electrical connection via other devices and connections.

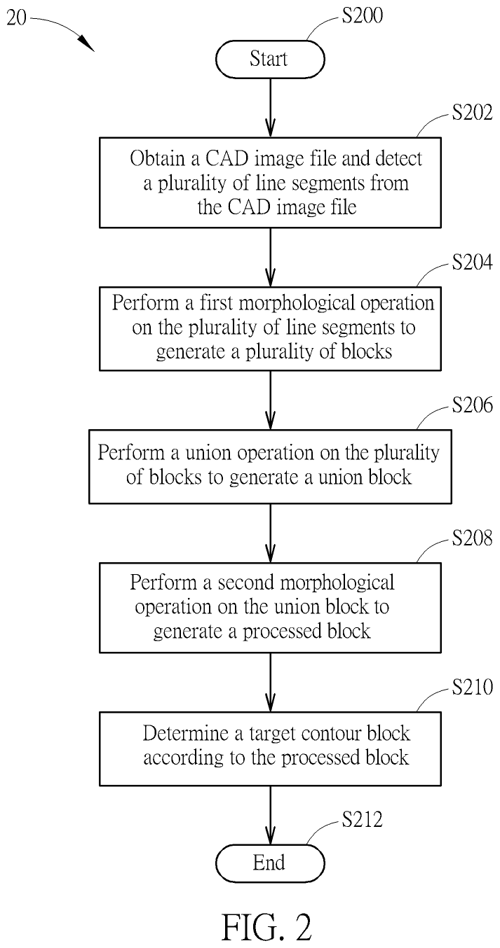

The embodiments of the present invention may be applied to the product design process using the computer-aided design (CAD), and the embodiments of the present invention may provide the conversion of the combination of line segments into the closed contour block during the design process. Please refer to FIG. 2. FIG. 2 is a flow diagram of a procedure 20 according to an embodiment of the present invention. The procedure 20 is utilized for processing line segments in a CAD image to generate a target contour block. The procedure 20 includes the following steps:
Step S200: Start.
Step S202: Obtain a CAD image file and detect a plurality of line segments from the CAD image file.
Step S204: Perform a first morphological operation on the plurality of line segments to generate a plurality of blocks.
Step S206: Perform a union operation on the plurality of blocks to generate a union block.
Step S208: Perform a second morphological operation on the union block to generate a processed block.
Step S210: Determine a target contour block according to the processed block.
Step S212: End.

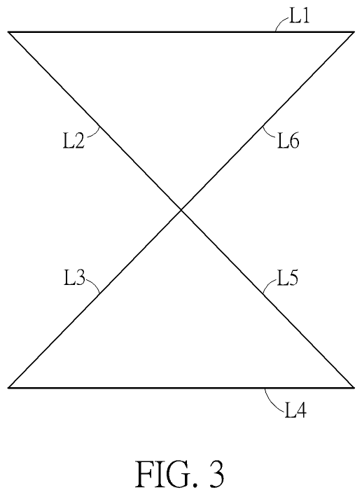

According to the procedure 20, in Step S202, the embodiments of the present invention may be executed on CAD software of an electronic device. The electronic device may include a computer device, and the computer device is equipped with CAD software. The CAD software may include AutoCAD, Pro/Engineer, SolidWorks, but not limited thereto. The embodiments of the present invention may generate a CAD image file through CAD software. The embodiments of the present invention may detect, identify and extract a plurality of line segments from the CAD image file by analyzing the CAD image file. The CAD image file may be a drawing interchange format (DXF) file or a AutoCAD drawing database (DWG) file, but not limited thereto. For example, please refer to FIG. 3. FIG. 3 is a schematic diagram illustrating line segments in a CAD image file according to an embodiment of the present invention. As shown in FIG. 3, the line segments L1-L6 may be detected from the CAD image file.

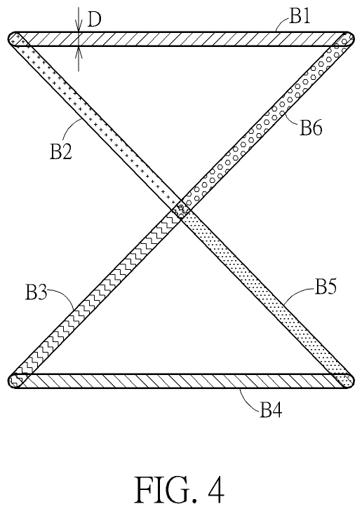

In step S204, a first morphological operation may be performed on the plurality of detected line segments to generate a plurality of blocks. For example, the first morphological operation may be a dilation operation. A dilation operation may be performed on the plurality of detected line segments to generate a plurality of blocks. Please refer to FIG. 3 and FIG. 4. FIG. 4 is a schematic diagram illustrating the blocks after dilation operation process according to an embodiment of the invention. As shown in FIG. 3, line segments L1-L6 may be detected from the CAD image file. As shown in FIG. 4, a dilation operation may be performed on the line segments L1-L6 to generate blocks B1-B6. For example, a dilation width of the dilation operation may be D. A software tool Shapely, hereafter referred to as Python package Shapely, is a package of Python program, and Python package Shapely is packaged by the spatial database extension package PostGIS for related geometric operations. In an embodiment, Python package Shapely may be utilized to perform a dilation operation on the line segments L1-L6 to generate blocks B1-B6.

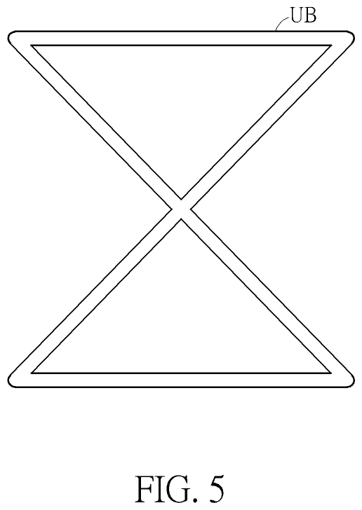

In step S206, a union operation may be performed on the blocks generated in step S204 to generate a union block (a single block). Please refer to FIG. 4 and FIG. 5. FIG. 5 is a schematic diagram illustrating the block after the union operation process according to an embodiment of the present invention. The blocks B1-B6 shown in FIG. 4 may be generated by performing the dilation operation on the line segments L1-L6, and a union operation may be performed on the dilated blocks B1-B6 to generate a union block UB shown in FIG. 5. For example, as shown in FIG. 5, Python package Shapely may be utilized to perform a union operation on the blocks B1-B6 processed by the dilation operation shown in FIG. 4 so as to generate the union block UB.

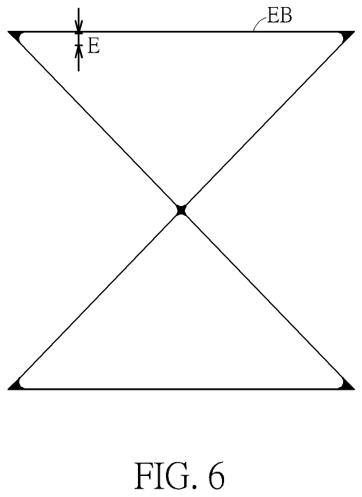

In step S208, a second morphological operation may be performed on the union block UB to generate a processed block. For example, the second morphological operation may be an erosion operation. An erosion operation may be performed on the union block to generate a processed block. Please refer to FIG. 5 and FIG. 6. FIG. 6 is a schematic diagram illustrating the blocks after erosion operation process according to an embodiment of the invention. As shown in FIG. 6, an erosion operation is performed on the union block UB of FIG. 5 to generate a processed block EB. For example, as shown in FIG. 6, an erosion thickness of the erosion operation may be E. For example, Python package Shapely may be utilized to perform an erosion operation on the union block UB to generate a processed block EB. In an embodiment, the erosion thickness E of the erosion operation utilized in Step S208 may be less than or equal to the dilation width D of the dilation operation utilized in Step S204.

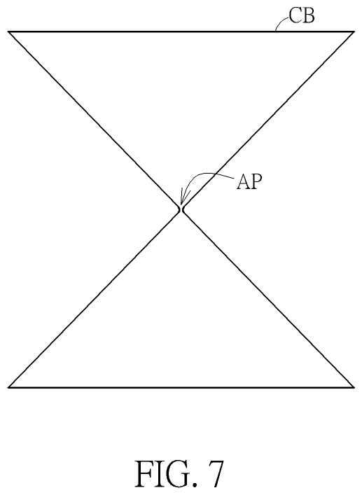

In step S210, a target contour block may be determined according to the processed block generated in Step S208. An outer contour of the processed block generated in Step S208 may be detected and extracted, and the detected outer contour of the processed block may be determining as a target contour block, such that the target contour block may be outputted for following estimation of the area ratio or weight of the object. Please refer to FIG. 6 and FIG. 7. FIG. 7 is a schematic diagram illustrating a target contour block according to an embodiment of the present invention. As shown in FIG. 7, the outer contour of the block EB of FIG. 6 may be detected and determined as a target contour block CB. As shown in FIG. 7, there is an opening AP between two triangles in the target contour block CB. For example, Python package Shapely may be utilized to extract the outer contour of the block EB of FIG. 6 to generate the target contour block CB. Please further refer to FIG. 6 and FIG. 7. Since a sharp point at the middle intersection of the original union block UB may be converted into an arc after performing the erosion operation. In Step S210, the target contour block CB obtained by extracting the outer contour of the block EB may include the opening AP, such that two triangles in the target contour block CB may be connected to each other and thus the target contour block CB may be a closed contour. In addition, the size of the opening AP between the two triangles in the target contour block CB is associated with the dilation width D of the dilation operation utilized in Step S204 and the erosion thickness E of the erosion operation utilized in Step S208.

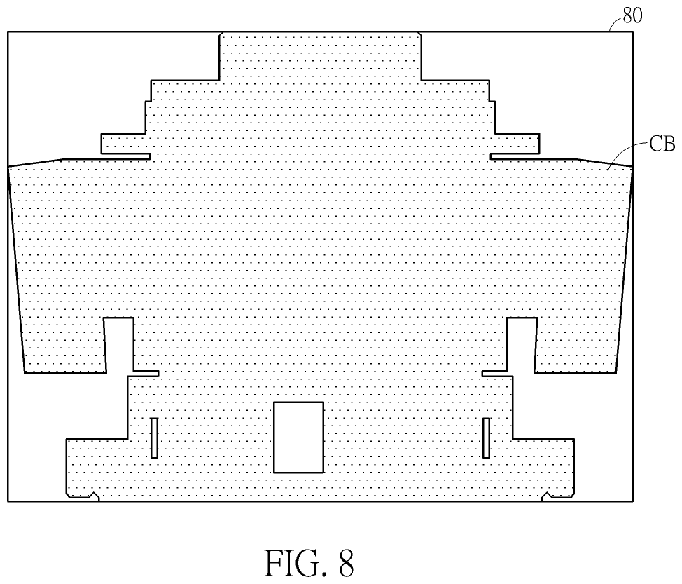

Conventional processing method typically determines object contour lines by detecting and connecting head and tail endpoints, which may cause misjudgment at the intersection of multiple similar line segments. Compared with conventional processing method, the embodiments of the present invention utilize image morphology operations to effectively and accurately convert discrete line segments into closed contours, thus greatly improving the accuracy of the subsequent estimation of area or weight of the product object. For example, please refer to FIG. 8. FIG. 8 is a schematic diagram illustrating a contour block of a product object according to an embodiment of the present invention. For example, if the product object is a packaging material. Through the aforementioned steps and methods of the embodiments of the present invention, cutting lines in the CAD image file of the packaging material may be converted into a complete closed contour block, such as the target contour block CB shown in FIG. 8. The minimum bounding rectangle (i.e., rectangle graph 80 shown in FIG. 8) of the closed contour block CB may be calculated for estimating cutting pattern of required material area.

Those skilled in the art should readily make combinations, modifications and/or alterations on the abovementioned description and examples. The abovementioned description, steps, procedures and/or processes including suggested steps can be realized by means that could be hardware, software, firmware (known as a combination of a hardware device and computer instructions and data that reside as read-only software on the hardware device), an electronic system or combination thereof. Examples of hardware can include analog, digital and/or mixed circuits known as microcircuit, microchip, or silicon chip. For example, the hardware may include application-specific integrated circuit (ASIC), field programmable gate array (FPGA), programmable logic device, coupled hardware components or combination thereof. In another example, the hardware may include general-purpose processor, microprocessor, controller, digital signal processor (DSP) or combination thereof. Examples of the software may include set (s) of codes, set (s) of instructions and/or set (s) of functions retained (e.g., stored) in a storage device, e.g., a non-transitory computer-readable medium. The non-transitory computer-readable storage medium may include read-only memory (ROM), flash memory, random access memory (RAM), subscriber identity module (SIM), hard disk, floppy diskette, or CD-ROM/DVD-ROM/BD-ROM, but not limited thereto. The embodiments of the invention may include an electronic system, and the electronic system may include a processing circuit and a storage device. Any of the abovementioned procedures and examples above may be compiled into program codes or instructions that are stored in the storage device or a computer-readable medium. The processing circuit may read and execute the program codes or the instructions stored in the storage device storage device or computer-readable medium for realizing the abovementioned functions.

To sum up, conventional processing method typically determines object contour lines by detecting and connecting head and tail endpoints, which may cause misjudgment at the intersection of multiple similar line segments. Compared with conventional processing method, the embodiments of the present invention utilize image morphology operations to effectively and accurately convert discrete line segments into closed contours, thus greatly improving the accuracy of the subsequent estimation of area or weight of the product object.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A contour line processing method, comprising
obtaining a computer-aided design (CAD) image file and detecting a plurality of line segments from the CAD image file;
performing a first morphological operation on the plurality of line segments to generate a plurality of blocks;
performing a union operation on the plurality of blocks to generate a union block;
performing a second morphological operation on the union block to generate a processed block; and
determining a target contour block according to the processed block.

2. The contour line processing method of claim 1, wherein the first morphological operation is a dilation operation.

3. The contour line processing method of claim 2, wherein the second morphological operation is an erosion operation.

4. The contour line processing method of claim 3, wherein an erosion thickness of the erosion operation is less than or equal to a dilation width of the dilation operation.

5. The contour line processing method of claim 1, wherein the step of determining the target contour block according to the processed block comprises detecting an outer contour of the processed block and determining the outer contour of the processed block as the target contour block.

6. An electronic device, comprising:
a storage device, configured to store instructions;
a processor circuit, configured to execute the instructions of:
obtaining a CAD image file and detecting a plurality of line segments from the CAD image file;
performing a first morphological operation on the plurality of line segments to generate a plurality of blocks;
performing a union operation on the plurality of blocks to generate a union block;
performing a second morphological operation on the union block to generate a processed block; and
determining a target contour block according to the processed block.

7. The electronic device of claim 6, wherein the first morphological operation is a dilation operation.

8. The electronic device of claim 7, wherein the second morphological operation is an erosion operation.

9. The electronic device of claim 8, wherein an erosion thickness of the erosion operation is less than or equal to a dilation width of the dilation operation.

10. The electronic device of claim 6, wherein the instructions further comprise:
detecting an outer contour of the processed block and determining the outer contour of the processed block as the target contour block.
